(19) United States
(12) Patent Application Publication
(10) Pub. No.: US 2019/0341745 A1
(43) Pub. Date: Nov. 7, 2019

(54) LASER DEVICE

(71) Applicant: SHIMADZU CORPORATION, Kyoto-shi, Kyoto (JP)

(72) Inventors: Junki SAKAMOTO, Kyoto-shi (JP); Jiro SAIKAWA, Kyoto-shi (JP); Koji TOJO, Kyoto-shi (JP)

(73) Assignee: SHIMADZU CORPORATION, Kyoto-shi, Kyoto (JP)

(21) Appl. No.: 16/333,458

(22) PCT Filed: Sep. 15, 2016
(86) PCT No.: PCT/JP2016/077228

§ 371 Date: Jul. 12, 2019

(51) Int. Cl. H01S 5/40; G02B 6/42; H01S 5/022; B23K 26/22

(52) U.S. Cl. CPC H01S 5/4012; G02B 6/4215; G02B 6/4272; B23K 26/22; H01S 5/02288; G02B 6/4214; G02B 6/4206

(57) ABSTRACT

A plurality of optical elements are provided in correspondence with a plurality of laser diodes, and make the plurality of beams emitted from the plurality of laser diodes parallel. A plurality of selective transmission elements are provided in correspondence with the plurality of optical elements and selectively transmit the beams emitted from the plurality of laser diodes or beams excluding an outer periphery portion of the beams emitted from the plurality of optical elements. One or more light traveling direction control members control light traveling directions of the plurality of beams having passed through the plurality of optical elements and the plurality of selective transmission elements so as to move the plurality of beams to the vicinity of an optical axis of the fiber. A light converging unit converges the plurality of beams emitted from the one or more light traveling direction control members to the fiber.

### CROSS REFERENCE TO RELATED APPLICATION

This application relates to, and claims priority from, Ser. No.: PCT/JP2016/077228 filed Sep. 15, 2016, the entire contents of which are incorporated herein by reference.

### FIGURE SELECTED FOR PUBLICATION

FIG. 1

### BACKGROUND OF THE INVENTION

### Field of the Invention

The present invention relates to a laser apparatus used for laser processing, laser welding, laser marking, and the like.

### Description of the Related Art

There is known a laser apparatus that couples beams emitted from a plurality of laser diodes (LD) to one fiber core to obtain a high output from a fiber.

Patent Document 1 (JP2005-114977A) describes a light power composing optical system capable of efficiently coupling light from a plurality of light sources to one light receiver to obtain a high output. According to this light power composing optical system, the magnification of the lens system can be reduced by making a luminous flux in the vertical direction and a luminous flux in the horizontal direction have equivalent magnitude by using an anamorphic optical element, and therefore the condensation diameter can be reduced. Therefore, the coupling efficiency to the light receiver can be improved, and thus a high-power laser beam can be obtained.

A beam emitted from a laser diode can be regarded as a Gaussian beam, and the product of a beam waist diameter w₀ and a beam divergence angle θ₀ is constant. Using a factor M² (M square) representing the beam quality, the relationship of these is expressed by Formula (1) using a wavelength λ.

M²=(Πw₀·θ₀)/λ (1)

The light emitting surface of the laser diode is a rectangle which is narrow in a lamination direction of the laser diode chip, that is, in a fast axis direction, and is wide in the lateral direction, that is, in a slow axis direction. It is known that the emitted beam has, as a result of diffraction, an elliptical shape spread in the fast axis direction. Assuming that the beam waist diameter is w₀f, the beam divergence angle is θ₀f, and the beam factor is M²f in the fast axis direction, and that the beam waist diameter is w₀s, the beam divergence angle is θ₀s, and the beam factor is M²s in the slow axis direction, this shape is represented by relationships of w₀s>w₀f, θ₀f>θ₀s, and M²f<M²s.

In a high-power laser diode, since the area of a light emitting surface of the laser diode chip represented by (2×w_{0f})×(2×w₀ₛ) is large. Therefore, the value of M² is worse than that of a laser diode of a transverse single mode, one can see that the beam quality is worse.

In addition, if a beam is incident on a core at an incident angle equal to or larger than the fiber NA (numerical aperture), total reflection does not occur between the core and the cladding, and the beam leaks to a resin layer and a protective layer covering the cladding and the surroundings thereof. Further, if a beam having a beam diameter equal to or larger than the core diameter of the fiber is incident on the core, the beam also leaks into the cladding. On the other hand, in order to reduce the size of the optical system after emission from the fiber and to reduce the diameter at the time of beam convergence after emission from the fiber, a fiber with a small NA and a small core diameter is required.

Therefore, when coupling a beam to a fiber having a small NA and a small core diameter, the beam is collected near the fiber axis (optical axis) by using a mirror, a prism, or the like, and the collimated beam is incident on a coupling lens in a direction perpendicular to the fiber axis. In this manner, a beam can be efficiently coupled to a fiber having a small NA and a small core diameter.

For example, beams emitted from a plurality of laser diodes can be coupled to a small core, for example, a fiber with a small NA of Φ 25, 50, or 100 um, and thus a beam of a high luminance and a high power can be obtained.

### RELATED ART DOCUMENTS

### Patent Document

Patent Document 1 JP 2005-114977 A

### Non Patent Document

Non Patent Document 1: Shimazu Review Vol. 71, no. 1⋅2 (2014. 9)

### ASPECTS AND SUMMARY OF THE INVENTION

### Objects to be Solved

However, a high-power laser diode has poorer beam quality than a laser diode with a low-power (single mode, etc.) light emitting surface, so that it is difficult to efficiently couple beams emitted from a plurality of laser diodes to a small core.

Further, in the case where the anamorphic optical element described in Patent Literature 1 is used, the cost of the optical element and the number of assembling and adjusting steps are increased. In the case of obtaining a high-luminance and high-power beam from a fiber of a small core, the proportion of energy loss in an incident portion of the fiber is large due to a loss, and therefore there is a tendency that the beam quality is degraded further by degradation of reliability caused by heating of the incident portion of the fiber or cladding leaked light.

The present invention provides a high-luminance and high-power laser apparatus capable of coupling beams to a smaller fiber core and improving beam quality.

### Means for Solving the Problem

In order to solve the problem described above, a laser apparatus according to the present invention is a laser apparatus for coupling a plurality of beams to a single fiber, the laser apparatus including a plurality of laser diodes that emit the plurality of beams, a plurality of optical elements provided in correspondence with the plurality of laser diodes to make the plurality of beams emitted from the plurality of laser diodes parallel, a plurality of selective transmission elements that are provided in correspondence with the plurality of optical elements and that selectively transmit the beams emitted from the plurality of laser diodes or beams excluding an outer periphery portion of the beams emitted from the plurality of optical elements, one or more light traveling direction control members that control light traveling directions of the plurality of beams having passed through the plurality of optical elements and the plurality of selective transmission elements so as to move the plurality of beams to the vicinity of an optical axis of the fiber, and a light converging unit that converges the plurality of beams emitted from the one or more light traveling direction control members to the fiber.

In addition, the present invention is a laser apparatus for coupling a plurality of beams to a single fiber, the laser apparatus including a plurality of laser diodes that emit the plurality of beams, a plurality of optical elements provided in correspondence with the plurality of laser diodes to make the plurality of beams emitted from the plurality of laser diodes parallel, one or more first light traveling direction control members that control light traveling directions of the plurality of beams emitted from the plurality of optical elements, a plurality of selective transmission elements that selectively transmit beams excluding an outer periphery portion of the beams emitted from the one or more first light traveling direction control members, one or more second light traveling direction control members that control light traveling directions of the plurality of beams emitted from the plurality of selective transmission elements so as to move the plurality of beams to the vicinity of an optical axis of the fiber, and a light converging unit that converges the plurality of beams emitted from the one or more second light traveling direction control members to the fiber.

### Effects of the Present Invention

According to the present invention, the plurality of selective transmission elements block a high M² component contained in an outer periphery portion of beams emitted from the laser diodes and selectively transmit only a low M² component included in beams excluding the outer periphery portion of the beams. Although the high M² component is a heat loss, by extracting only the low M² component, it is possible to reduce the spot diameter and the incident angle when converging a plurality of beams. Therefore, it is possible to couple the beams to a fiber core smaller than a conventional fiber core.

Accordingly, by narrowing the distance between the one or more light traveling direction control members constituted by mirrors, prisms, or the like, that is, by narrowing the interval between the beams, the number of beams projected onto a coupling lens (light converging unit) arranged before a fiber can be increased, and thus a larger number of beams can be coupled to the fiber core.

By removing the high M² component, a loss occurs in the power of each laser diode, but a beam filling factor that can be coupled to one fiber (the sum of sectional areas of beams on the coupling lens/an effective area contributing to fiber coupling on the coupling lens) increases, so that a high output can be achieved in total. In addition, increasing the beam filling factor means that the beams can be collected to the vicinity of the optical axis of the coupling lens, and the fiber incident NA can be reduced. That is, it is possible to use a low NA fiber capable of obtaining a beam with a higher luminance. Since the component which becomes cladding leakage is removed in an early stage, the fiber output beam quality is improved.

In addition, it becomes possible to reduce the diameter of the laser diode output beam, and thus it is possible to miniaturize optical members such as lenses, mirrors, prisms, wavelength plates, and the like to be used in later stages.

### BRIEF DESCRIPTION OF THE DRAWINGS

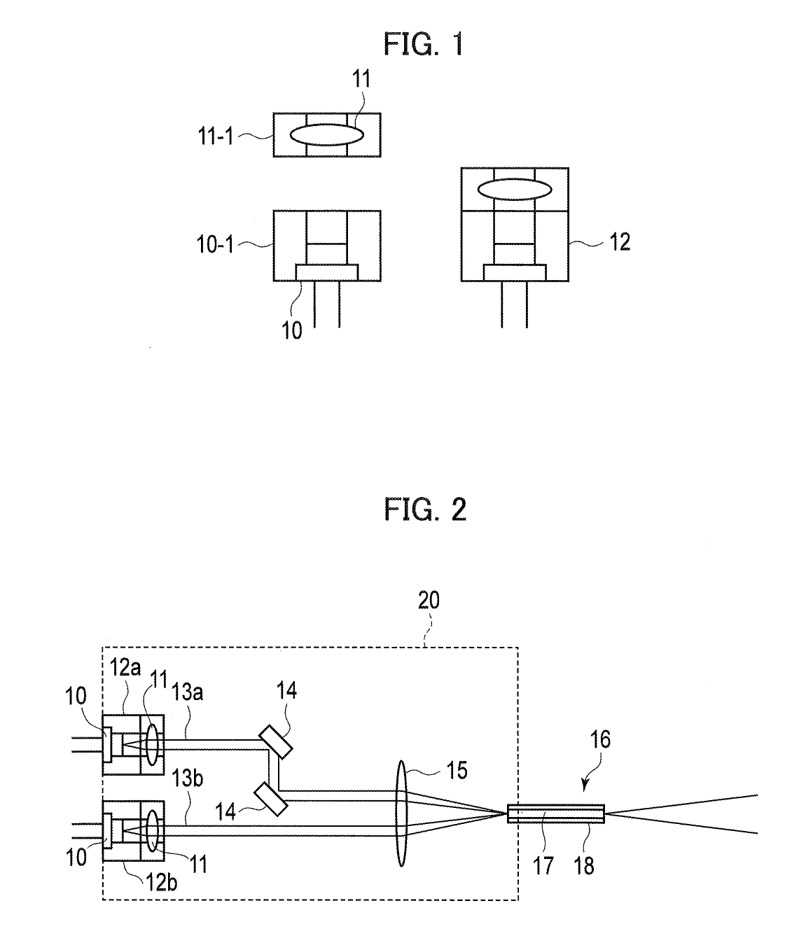

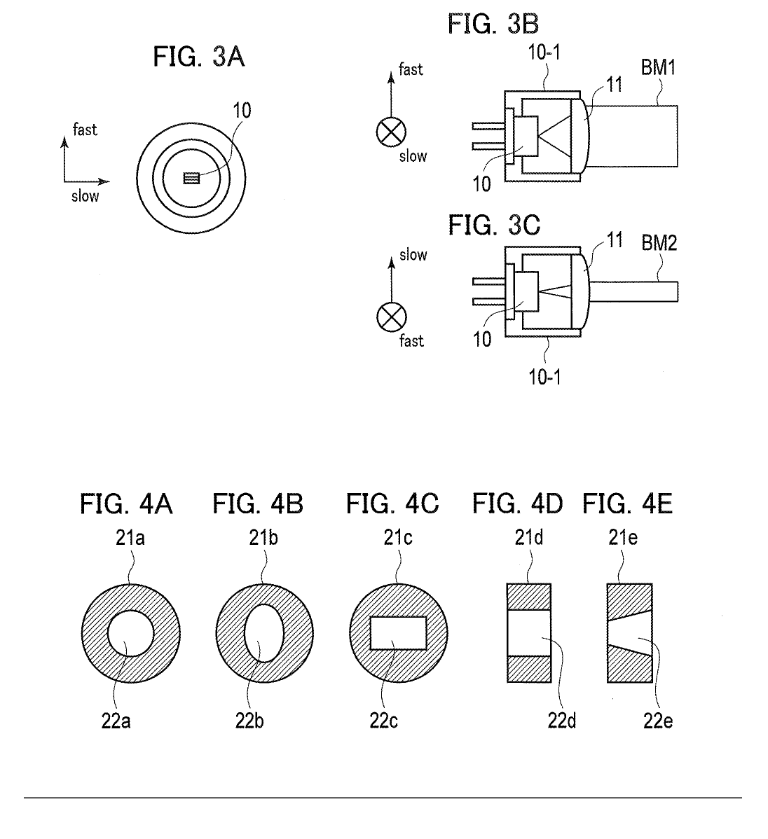

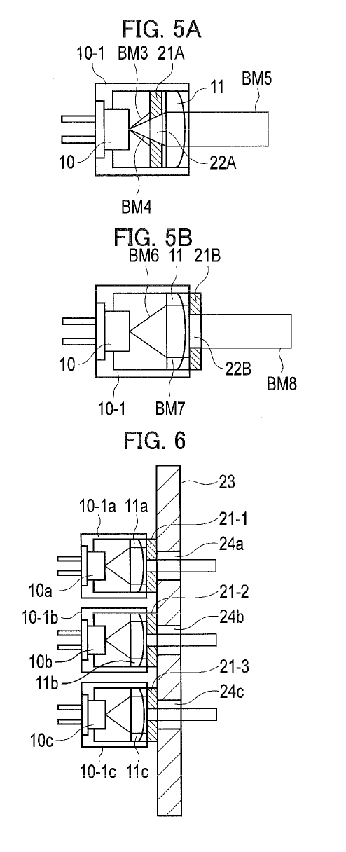

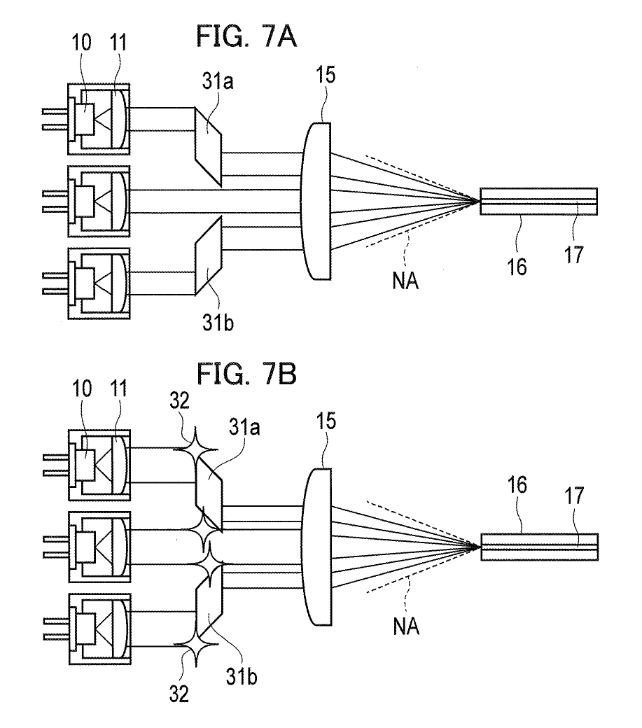

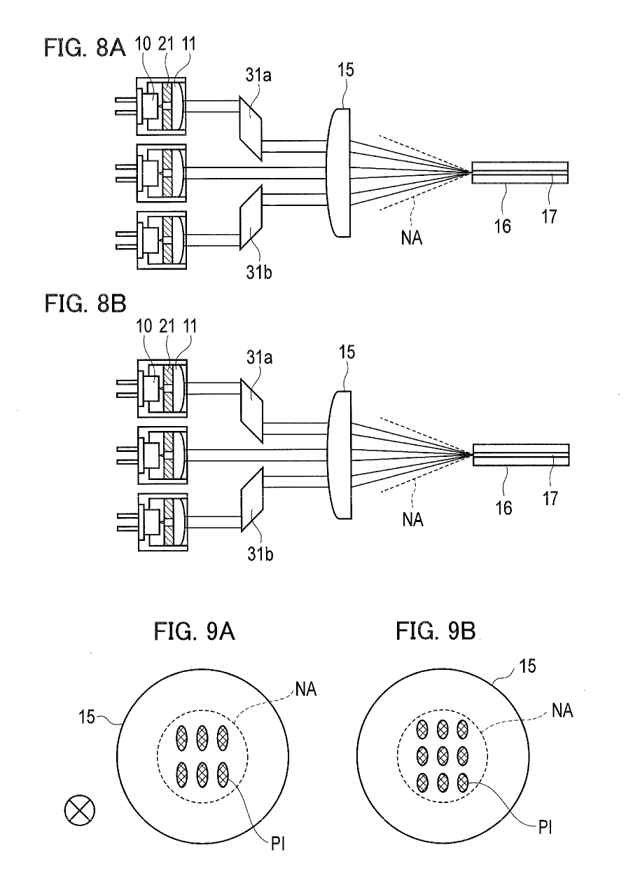

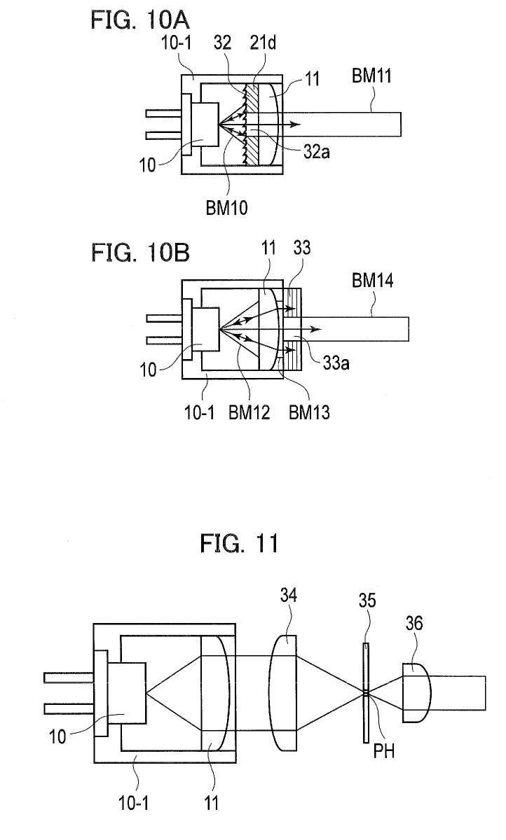

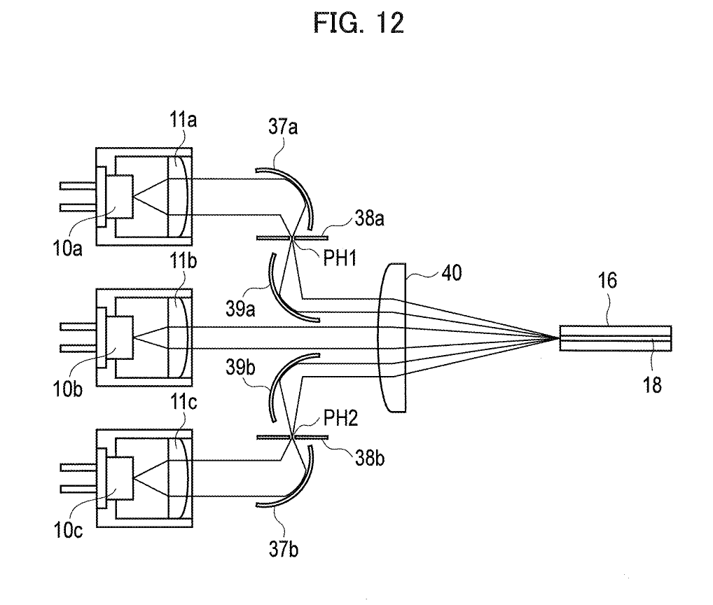

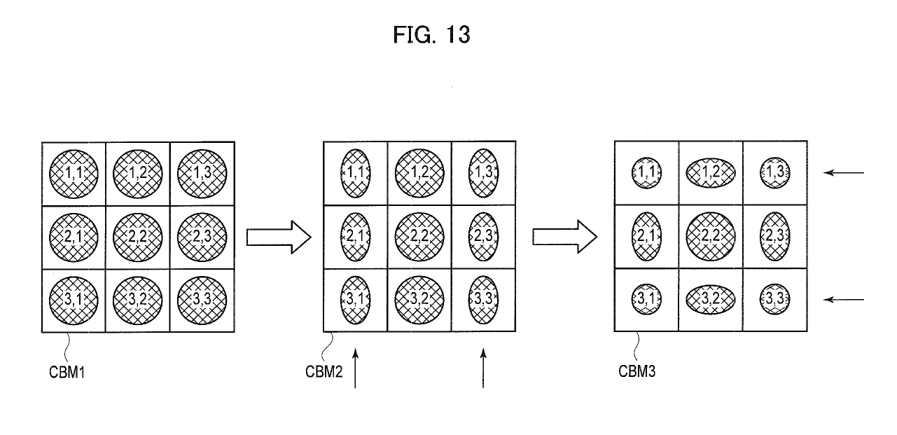

FIG. 1 is a diagram illustrating a configuration of a unit including a collimating lens holder and an LD holder in a laser apparatus according to an embodiment of the present invention.

FIG. 2 is an overall configuration diagram of the laser apparatus according to the embodiment of the present invention.

FIGS. 3A to 3C show diagrams illustrating divergence of beams in a fast axis direction and a slow axis direction of a laser diode of the laser apparatus according to the embodiment of the present invention.

FIGS. 4A to 4E show diagrams illustrating the shape of a diaphragm member of the laser apparatus according to the first embodiment of the present invention.

FIGS. 5A and 5B show diagrams illustrating a diaphragm member attached to the front or rear of a collimating lens in the laser apparatus according to the first embodiment of the present invention.

FIG. 6 is a diagram illustrating a configuration example in which heat in the diaphragm member is dissipated by a radiator plate in the laser apparatus according to the first embodiment of the present invention.

FIGS. 7A and 7B show configuration diagrams of a conventional laser apparatus that does not include a diaphragm member.

FIGS. 8A and 8B show configuration diagrams of the laser apparatus according to the first embodiment of the present invention including a diaphragm member.

FIGS. 9A and 9B show diagrams illustrating a beam filling factor in the case where no diaphragm member is provided and a beam filling factor in the case where a diaphragm member is provided.

FIGS. 10A and 10B show configuration diagrams of a laser apparatus according to a second embodiment of the present invention including a diaphragm member including a diffraction grating.

FIG. 11 is a configuration diagram of a laser apparatus according to a third embodiment of the present invention including a pinhole.

FIG. 12 is a configuration diagram of a laser apparatus according to a fourth embodiment of the present invention including concave mirrors and pinholes.

FIG. 13 is a diagram illustrating a sequence in the case where beams are passed through the pinholes by the concave mirrors in the laser apparatus according to the fourth embodiment of the present invention.

### DETAILED DESCRIPTION OF THE PREFERRED EMBODIMENTS

### First Embodiment

Hereinafter, a laser apparatus according to an embodiment of the present invention will be described in detail with reference to drawings.

### (Basic Configuration of Present Invention)

First, a basic configuration of the laser apparatus of the present invention will be described. FIG. 1 is a diagram illustrating a configuration of a unit 12 including a collimating lens holder 11-1 and an LD holder 10-1 in a laser apparatus according to an embodiment of the present invention. FIG. 2 is an overall configuration diagram of the laser apparatus according to the embodiment of the present invention.

The laser apparatus includes a plurality of laser diodes 10, a plurality of collimating lenses 11 (corresponding to optical elements of the present invention) provided in correspondence with the plurality of laser diodes 10, a plurality of units 12 provided in correspondence with the plurality of laser diodes 10 and formed by fixing the laser diodes 10 and the collimating lenses 11 for the respective laser diodes 10, a coupling lens 15 (corresponding to a light converging unit of the present invention) for converging beams emitted from the laser diodes 10 to a fiber 16, and a holder 20 that accommodates the plurality of units 12 and the coupling lens 15.

As illustrated in FIG. 1, a laser diode 10 is fixed to the LD holder 10-1, and a collimating lens 11 is fixed to the collimating lens holder 11-1. The unit 12 can be manufactured by fixing the LD holder 10-1 and the collimating lens holder 11-1 together by welding while confirming that a collimating beam is emitted from the LD holder 10-1 and the collimating lens holder 11-1 in a predetermined acceptable range. By repeating the above process, the plurality of units 12 are manufactured.

FIG. 2 illustrates an example in which two units 12 are provided. The number of the units 12 is not limited to two, and may be three or more. As illustrated in FIG. 2, units 12a and 12b are arranged apart from each other by a predetermined distance, and are accommodated and fixed in the holder 20. The holder 20 further accommodates two mirrors 14 and the coupling lens 15. The fiber 16 composed of a core 17 and a cladding 18 is arranged outside the holder 20 so as to face the coupling lens 15.

As illustrated in FIG. 2, the traveling direction of a beam 13a emitted from the unit 12a is controlled by the mirror 14, and the beam 13a travels to the coupling lens 15 so as to be coupled to the core 17 of the fiber 16. The positions of the unit 12a and the unit 12b are adjusted such that the beam from the unit 12a and the beam from the unit 12b are converged by the coupling lens 15 and coupled to the core 17, and the distance between each of the unit 12a and 12b and the holder 20 is fixed by laser welding.

FIG. 3A illustrates a structure of the LD holder 10-1 of the laser apparatus according to the embodiment of the present invention, FIG. 3B illustrates divergence of a beam in a fast axis direction, and FIG. 3C illustrates divergence of the beam in a slow axis direction. With respect to the beam emitted from the laser diode 10, the divergence of the beam in the fast axis direction (lamination direction) of a laser chip is wider than in the slow axis direction (horizontal direction).

### (Characteristic Element of Present Invention)

Next, a diaphragm member serving as a characteristic element of the present invention will be described. FIGS. 4A to 4C illustrate shapes of diaphragm members 21a to 21c of the laser apparatus according to the first embodiment, and FIGS. 4D and 4E are diagrams illustrating sectional shapes of the diaphragm member. The diaphragm members 21a to 21c correspond to selective transmission elements of the present invention, and selectively transmit beam excluding the outer periphery portion of the beams emitted from the laser diodes 10 or the beams emitted from the collimating lenses 11. That is, the diaphragm members 21a to 21c block a high M² component contained in the outer periphery portion of the beams emitted from the laser diodes and selectively transmit only a low M² component included in the beams excluding the outer periphery portion of the beams. To be noted, the high M² component refers to a component of beams spread in both the fast axis direction and the slow axis direction, and is not limited to one of the axes.

The diaphragm member 21a illustrated in FIG. 4A is formed by boring a circular hole 22a in a center portion of a circular aluminum bar material. The diaphragm member 21b illustrated in FIG. 4B is formed by boring an elliptical hole 22b in a center portion of a circular aluminum bar material. The diaphragm member 21c illustrated in FIG. 4C is formed by boring a quadrangular hole 22c in a center portion of a circular aluminum bar material. Only the low M² component can be transmitted through the holes 22a to 22c.

Further, a substance having a predetermined absorption coefficient to the wavelength of the beams emitted from the laser diodes 10 may be formed on the surfaces of the diaphragm members 21a to 21c. For example, by subjecting the surfaces of the diaphragm members 21a to 21c to black alumite treatment, it is possible to reduce reflected beams to efficiently absorb unnecessary beams. Instead of subjecting the surfaces of the diaphragm members 21a to 21c to black alumite treatment, a dielectric thin film may be applied.

Further, as examples of sections of the diaphragm members 21a to 21c, a diaphragm member 21d having a quadrangular hole portion 22d illustrated in FIG. 4D and a diaphragm member 21e having a tapered hole portion 22e illustrated in FIG. 4E can be shown. By setting the taper angle of the hole portion 22e equal to the target beam divergence angle to matching the position of the apex of a cone formed by the taper angle with the position of the beam waist, it is possible to extract only the low M² component more effectively. It is also possible to adjust the position of the diaphragm members back and forth according to the variation in the beam divergence angles of the laser diodes 10.

The diaphragm member 21A illustrated in FIG. 5A is attached in front of the collimating lens 11, that is, between the laser diode 10 and the collimating lens 11. The diaphragm member 21A has a tapered hole portion 22A. A beam BM4 passing through the hole portion 22A of the diaphragm member 21A among a beam BM3 from the laser diode 10 is collimated by the collimating lens 11 and thus a collimated beam BM5 is obtained.

Further, the diaphragm member 21B illustrated in FIG. 5B is attached behind the collimating lens 11. The diaphragm member 21B has a quadrangular hole portion 22B. A beam BM6 from the laser diode 10 is collimated by the collimating lens 11, and thus a collimated beam BM7 is obtained. Among the collimated beam BM7, only a beam BM8 is transmitted and obtained through the hole portion 22B of the diaphragm member 21B. The LD holder 10-1 and the collimating lens holder 11-1 may also play the role of the diaphragm member 21 without additionally preparing the diaphragm member 21.

FIG. 6 is a diagram illustrating a configuration example in which heat in the diaphragm member is dissipated by a radiator plate in the laser apparatus according to the first embodiment of the present invention. As described above, when the diaphragm member 21 is subjected to alumite treatment, the high M² component can be removed, but the diaphragm member 21 is likely to generate heat. For this reason, as illustrated in FIG. 6, a radiator plate 23 is provided in contact with diaphragm members 21-1 to 21-3. Hole portions 24a to 24c are formed in correspondence with the diaphragm members 21-1 to 21-3 in the radiator plate 23, and beams transmitted through the diaphragm members 21-1 to 21-3 pass through the hole portions 24a to 24c of the radiator plate 23. By bringing the radiator plate 23 into contact with the diaphragm members 21-1 to 21-3, heat generation of the diaphragm members 21-1 to 21-3 can be suppressed.

In addition, the distance between the diaphragm members 21-1 to 21-3 and the radiator plate 23 may change due to a positional shift between the LD holders 10-1 and the collimating lens holders 11-1. In this case, by inserting a heat transfer material between the diaphragm members 21-1 to 21-3 and the radiator plate 23, heat can be efficiently dissipated by the heat transfer material.

FIG. 7 is a configuration diagram of a conventional laser apparatus that does not include a diaphragm member 21. FIG. 8 is a configuration diagram of the laser apparatus according to the first embodiment of the present invention including diaphragm members 21. FIGS. 7A and 8A are configuration diagrams of the laser apparatuses in the slow axis direction. FIGS. 7B and 8B are configuration diagrams of the laser apparatuses in the fast axis direction.

The conventional laser apparatus illustrated in FIG. 7 includes a plurality of laser diodes 10, a plurality of collimating lenses 11, prisms 31a and 31b that control light traveling directions of a plurality of beams having passed through the plurality of collimating lenses 11 so as to move the plurality of beams onto the optical axis of a fiber 16, and a coupling lens 15 for converging the plurality of beams emitted from the prisms 31a and 31b to the fiber 16.

As illustrated in FIG. 7B, in the conventional laser apparatus, a vignetting portion 32 where a part of the collimated beams from the collimating lens 11 leaks to the outside of the prisms 31a and 31b is generated. Therefore, the laser apparatus of the first embodiment illustrated in FIG. 8 further includes diaphragm members 21 in addition to the conventional laser apparatus illustrated in FIG. 7. By excluding the outer periphery portion of the collimated beams by the diaphragm members 21 and outputting the narrowed beams to the prisms 31a and 31b, the occurrence of the vignetting portion 32 in the prisms 31a and 31b is prevented.

A plurality of laser diodes 10, a plurality of collimating lenses 11, a plurality of diaphragm members 21, prisms 31a and 31b that control light traveling directions of a plurality of beams having passed through the plurality of collimating lenses 11 so as to move the plurality of beams onto the optical axis of a fiber 16, and a coupling lens 15 for converging the plurality of beams emitted from the prisms 31a and 31b to the fiber 16 are provided.

Next, description will be given by exemplifying that the beam filling factor is improved by using the diaphragm member 21. It is assumed that the intensity distribution of a beam emitted from a laser diode is a perfect Gaussian distribution. Assuming a point where the intensity of the Gaussian beam takes the maximum value Io, an intensity I(r) at a point distant from the central axis by a distance r on a plane perpendicular to the beam traveling direction is expressed by the following formula (2).

I(r)=I₀ exp(−2r²/w₀²) (2)
w₀ is called the beam radius, and within the beam radius w₀, 1−1/e²=86.5% of the total power of the beam exists. Here, arranging the diaphragm member 21 that can transmit only components of 2.0, 1.5, 1.2, 1.0, and 0.8 times the beam diameter in the fast axis direction and the slow axis direction in front of or behind the collimating lens is considered.

At this time, the power of the beam passing through the diaphragm member 21 is 99.97%, 98.89%, 94.39%, 86.47%, and 72.2%, respectively. It can be seen that when the diameter of the diaphragm member 21 is reduced, the power of the beam transmitted through the diaphragm member 21 is reduced.

Here, among the beams incident on the coupling lens 15, letting D be a diameter on the lens effective for fiber core coupling, a case where a plurality of beams are coupled to the core 17 of the fiber 16 as illustrated in FIGS. 7 and 8 is considered. When the beam positions are shifted by the prisms 31a and 31b, the lower limit of the interval between the beams after shifting is set as d. At this time, the power obtained when utilizing the diaphragm member capable of transmitting only the component of M times the beam diameter w₀ is M×w₀×N+d×(N−1)<D, assuming that the maximum number of beams is N. That is, N<(D+d)/(M×w₀+d) holds. D is the diameter on the lens effective for fiber core coupling. M is a positive integer. Here, when D=5w₀ and d=0.2w₀ are satisfied, the maximum number of beams N satisfies N<5.2/(M+0.2). To be noted, N is represented by the largest positive integer satisfying the inequality. The maximum number of beams N when using a diaphragm member that can transmit only components of 2.0, 1.5, 1.2, 1.0, and 0.8 times the beam diameter is 2, 3, 3, 4, and 5, respectively, and are respectively 199.9%, 296.7%, 283.2%, 345.9%, and 361.0% when the power before being incident on the diaphragm member of a laser diode 1pc is 100%. Therefore, it can be seen that the fiber incident power can be maximized by improving the beam filling factor when the diaphragm member 21 is used.

In the above example, although an example of using the diaphragm member 21 in both the fast axis direction and the slow axis direction has been described, it is also possible to use a diaphragm member having an arbitrary size in the fast axis direction or slow axis direction in accordance with the core diameter and the core shape of the fiber to be used.

FIG. 9A is a diagram illustrating a beam filling factor in the case where the diaphragm member 21 is not provided, and FIG. 9B illustrates a beam filling factor in the case where the diaphragm member 21 having a transmittance of 0.8 is provided. In FIG. 9A, six projected images PI fill the NA of the core. In FIG. 9B, nine projected images PI fill the NA of the core. When the output of one beam is P and the fiber output is Po, Po=6 beams×P=6P in FIG. 9A. In FIG. 9B, Po=transmittance 0.8×(9 beams×P)=7.2P. That is, the use of the diaphragm member 21 results in higher luminance and higher output.

As described above, according to the laser apparatus of the first embodiment, the plurality of diaphragm members 21 block a high M² component contained in an outer periphery portion of beams emitted from the laser diodes and selectively transmit only a low M² component included in beams excluding the outer periphery portion of the beams. Although the high M² component is a heat loss, by extracting only the low M² component, it is possible to reduce the spot diameter and the incident angle when converging a plurality of beams. Therefore, it is possible to couple the beams to a fiber core smaller than a conventional fiber core.

Accordingly, by narrowing the distance between the prisms 31a and 31b, that is, by narrowing the interval between the beams, the number of beams projected onto the coupling lens 15 arranged before the fiber 16 can be increased, and thus a larger number of beams can be coupled to the core 17 of the fiber 16.

By removing the high M² component, a loss occurs in the power of each laser diode 10, but a beam filling factor that can be coupled to one fiber 16 (the sum of sectional areas of beams on the coupling lens/an effective area contributing to fiber coupling on the coupling lens) increases, so that a high output can be achieved in total. In addition, increasing the beam filling factor means that the beams can be collected to the vicinity of the optical axis of the coupling lens, and the fiber incident NA can be reduced. That is, it is possible to use a low NA fiber of a higher luminance. Since the component which becomes cladding leakage is removed in an early stage, damage to the fiber 16 is reduced, and the fiber output beam quality is improved.

In addition, it becomes possible to reduce the diameter of the laser diode output beam, and thus it is possible to miniaturize optical members such as lenses, mirrors, prisms, wavelength plates, and the like to be used in later stages.

### Second Embodiment

The spectral linewidth of a laser diode 10 of a transverse multimode is wider than that of a laser diode 10 of a transverse single mode. In applications requiring a high intensity and a narrow spectral line width such as a light source for fluorescence excitation, it is necessary to improve the spectral line width. Therefore, a laser apparatus according to a second embodiment of the present invention is characterized in that the spectral line width is improved by using a diffraction grating-incorporating diaphragm.

FIG. 10A is a diagram illustrating a case where a diffraction grating-incorporating diaphragm member 21d is provided in front of the collimating lens 11 in the laser apparatus according to the second embodiment of the present invention. FIG. 10B is a diagram illustrating a case where a diffraction grating-incorporating diaphragm member 33 is provided behind the collimating lens 11 in the laser apparatus according to the second embodiment of the present invention.

As illustrated in FIG. 10A, when the diffraction grating-incorporating diaphragm member 21d is arranged on the incident side, since the laser diode beam has a divergence angle, the incident angle on the diffraction grating-incorporating diaphragm member 21d is a non-zero value. Therefore, a blazed diffraction grating is used, and a Littrow configuration in which light returns to the direction of incident light is adopted.

That is, the diffraction grating-incorporating diaphragm member 21d corresponds to a reflection-type diffraction grating of the present invention, and returns, to a light emitting surface of a laser diode 10, a part of a beam BM10 emitted from a laser diode 10 to a surface facing the laser diode 10, and a beam BM11 is obtained by a hole portion 32a.

As illustrated in FIG. 10B, when the diffraction grating-incorporating diaphragm member 33 is arranged behind the collimating lens 11, the incident angle of the beam on the diffraction grating becomes almost zero, and therefore a volume holographic grating (VHG) can be used. Also in this case, a part of the beam BM10 emitted from the laser diode 10 is returned to the light emitting surface of the laser diode 10.

According to the above configuration, an external resonator is formed between the laser diode 10 and the diffraction grating-incorporating diaphragm member 21d and 33. A component having a low M² value passes through the diffraction grating-incorporating diaphragm members 21d and 33, and a component having a high M² value is returned to the light emitting surface of the laser diode 10. Therefore, it is possible to realize both of reducing the linewidth of and stabilizing the wavelength of the laser wavelength, and increasing the output.

### Third Embodiment

FIG. 11 is a configuration diagram of a laser apparatus according to a third embodiment of the present invention including a pinhole. FIG. 11 is the laser apparatus according to the third embodiment of the present invention is characterized in that a condensing lens 34, a pinhole 35, and a collimating lens 36 are provided behind the collimating lens 11.

The condensing lens 34 condenses a beam collimated by the collimating lens 11 to a hole PH formed in the pinhole 35. The pinhole 35 removes the high M² component at the hole PH, and thus extracts and outputs only the low M² component to the collimating lens 36. The collimating lens 36 collimates the beam of only the low M² component extracted by the pinhole 35.

In this manner, the same effect as that of the laser apparatus according to the first embodiment can be achieved also by the laser apparatus including the pinhole according to the third embodiment.

### Fourth Embodiment

FIG. 12 is a configuration diagram of a laser apparatus according to a fourth embodiment of the present invention including concave mirrors and pinholes. The laser apparatus illustrated in FIG. 12 includes a plurality of laser diodes 10a to 10c, cylindrical concave mirrors 37a and 37b that control the light traveling directions of a plurality of beams emitted from a plurality of collimating lenses 11a to 11c, pin holes 38a and 38b that selectively transmit beams excluding an outer periphery portion of the plurality of beams emitted from the cylindrical concave mirrors 37a and 37b, cylindrical concave mirrors 39a and 39b that control the light traveling directions of the plurality of beams emitted through the pinholes 38a and 38b so as to move the plurality of beams onto the optical axis of a fiber 16, and a coupling lens 40 that converges the plurality of beams emitted from the cylindrical concave mirrors 39a and 39b to the fiber 16. To be noted, slits may be used in place of the pinholes 38a and 38b.

Regarding the plurality of laser diodes 10a to 10c, three laser diodes are arranged in the vertical direction as illustrated in FIG. 12. Further, regarding the plurality of laser diodes, although illustration thereof is omitted, three laser diodes are arranged in the horizontal direction, and a total of nine laser diodes are arranged in the vertical direction and the horizontal direction. The cylindrical concave mirrors 37a and 37b correspond to one or more first light traveling direction control members of the present invention. The pinholes 38a and 38b correspond to plurality of selective transmission elements of the present invention. The cylindrical concave mirrors 39a and 39b correspond to one or more second light traveling direction control members of the present invention and are arranged to face the cylindrical concave mirrors 37a and 37b with the pinholes 38a and 38b therebetween. The coupling lens 40 corresponds to a converging unit.

According to such a configuration, beams emitted from the laser diodes 10a to 10c become collimated beams by the collimating lenses 11a to 11c arranged at focal positions. The collimated beams are reflected by the cylindrical concave mirrors 37a and 37b, and the high M² component in the vertical direction or the horizontal direction is removed by the pinholes 38a and 38b arranged at the focal positions of the cylindrical concave mirrors 37a and 37b.

The beams that have passed through the pinholes 38a and 38b become collimated beams again by the cylindrical concave mirrors 39a and 39b and travel in the optical axis direction (axis perpendicular to the fiber 16). The position of each collimated beam can be shifted toward the center of the optical axis of the coupling lens 40, so that it is possible to reduce the fiber NA while reducing the influence of aberration in the coupling lens 40. In addition, since the number of beams that can be incident on the coupling lens 40 increases, the output can be increased.

Also, depending on the positions and shapes of the cylindrical concave mirrors 37a, 37b, 39a, and 39b, the shapes of the collimated beams after reflection by the cylindrical concave mirrors 37a, 37b, 39a, and 39b can be freely controlled.

FIG. 13 is a diagram illustrating a sequence in the case where beams are passed through the pinholes 38a and 38b by the cylindrical concave mirrors 37a and 37b in the laser apparatus according to the fourth embodiment of the present invention. As described with reference to FIG. 12, regarding the plurality of laser diodes, nine laser diodes are arranged in a matrix of (1, 1) to (3, 3) in the vertical direction (row direction) and the horizontal direction.

### (Column Direction).

The beams of the nine laser diodes 10 become nine circular collimated beams CBM1 as a result of the nine collimating lenses 11. The sizes of the circles of the collimated beams CBM1 indicate an initial M2 value.

Next, as indicated by vertical arrows, when the pinholes 38 are applied to the horizontal direction of the first column (1, 1), (2, 1), and (3, 1) and the third column (1, 3), (2, 3), and (3, 3) of the plurality of laser diodes, the collimated beams CBM1 of the first column (1, 1), (2, 1), and (3, 1) and the third column (1, 3), (2, 3), and (3, 3) are reduced in the horizontal direction, and thus beams CBM2 are obtained. Therefore, the high M² component in the horizontal direction is removed.

Next, as indicated by horizontal arrows, when the pinholes 38 are applied to the vertical direction of the first row (1, 1), (1, 2), and (1, 3) and the third row (3, 1), (3, 2), and (3, 3) of the plurality of laser diodes, the collimated beams CBM2 of the first row (1, 1), (1, 2), and (1, 3) and the third row (3, 1), (3, 2), and (3, 3) are reduced in the vertical direction, and thus beams CBM3 are obtained. Therefore, the high M² component in the vertical direction is removed.

As described above, for the beams emitted from the nine laser diodes 10, the high M² component of beams at positions affected by the aberration of the coupling lens is removed depending on the positional relationship with the optical axis, the diameters of the collimated beams are reduced, and thus the filling factor of the beams can be improved.

To be noted, regarding the laser diode at the center of the matrix (2, 2), the high M² component has not passed through a pinhole or a slit and thus remains. However, since the central laser diode is arranged on the optical axis, the central laser diode is the least likely to be affected by the aberration of the coupling lens, and therefore the high M² component being included is not a big problem.

Similarly, for the beams CBM3 in (1, 2), (2, 1), (2, 3), and (3, 2) of the matrix, the high M² component has not been removed for one axis, but the effect thereof is small as compared with the laser diode of the four corners (1, 2, (1, 3), (3, 1), and (3, 3) of the matrix.

To be noted, if necessary, in order to remove the high M² component, the pinhole 35 and the collimating lens 36 described in the third embodiment may be added behind the coupling lens 40.

### INDUSTRIAL APPLICABILITY

The present invention is applicable to a fine laser processing machine used for soldering, bonding wire connection, substrate welding of electronic parts, minute spot annealing, and the like.

1. A laser apparatus for coupling a plurality of beams to a single fiber, the laser apparatus comprising:
a plurality of laser diodes that emit the plurality of beams;
a plurality of optical elements provided in correspondence with the plurality of laser diodes to make the plurality of beams emitted from the plurality of laser diodes parallel;
a plurality of selective transmission elements that are provided in correspondence with the plurality of optical elements and that selectively transmit the beams emitted from the plurality of laser diodes or beams excluding an outer periphery portion of the beams emitted from the plurality of optical elements;
one or more light traveling direction control members that control light traveling directions of the plurality of beams having passed through the plurality of optical elements and the plurality of selective transmission elements so as to move the plurality of beams to the vicinity of an optical axis of the fiber; and
a light converging unit that converges the plurality of beams emitted from the one or more light traveling direction control members to the fiber.

2. The laser apparatus according to claim 1, wherein a substance having a predetermined absorption coefficient to wavelengths of the plurality of beams emitted from the plurality of laser diodes is formed on a surface of each of the plurality of selective transmission elements.

3. The laser apparatus according to claim 1, wherein a radiator plate for dissipating heat of the plurality of selective transmission elements is attached to each of the plurality of selective transmission elements.

4. The laser apparatus according to claim 1, wherein a reflection-type diffraction grating that returns a part of the plurality of beams emitted from the plurality of laser diodes to light emitting surfaces of the plurality of laser diodes is formed on a surface of each of the plurality of selective transmission elements, and an external resonator is constituted between the plurality of laser diodes and the reflection-type diffraction grating.

5. A laser apparatus for coupling a plurality of beams to a single fiber, the laser apparatus comprising:
a plurality of laser diodes that emit the plurality of beams;
a plurality of optical elements provided in correspondence with the plurality of laser diodes to make the plurality of beams emitted from the plurality of laser diodes parallel;
one or more first light traveling direction control members that control light traveling directions of the plurality of beams emitted from the plurality of optical elements;
a plurality of selective transmission elements that selectively transmit beams excluding an outer periphery portion of the plurality of beams emitted from the one or more first light traveling direction control members;
one or more second light traveling direction control members that control light traveling directions of the plurality of beams emitted from the plurality of selective transmission elements so as to move the plurality of beams to the vicinity of an optical axis of the fiber; and
a light converging unit that converges the plurality of beams emitted from the one or more second light traveling direction control members to the fiber.

6. The laser apparatus according to claim 5, wherein the one or more first light traveling direction control members and the one or more second light traveling direction control members are concave mirrors, and the plurality of selective transmission elements are pinholes or slits.
